(19) United States
(12) Patent Application Publication
(10) Pub. No.: US 2025/0301796 A1
(43) Pub. Date: Sep. 25, 2025

(54) INPUT/OUTPUT DRIVER

(71) Applicant: Winbond Electronics Corp., Taichung City (TW)

(72) Inventors: Shu Yuan Hsu, Taichung City (TW); Chao-Lung Wang, Taichung City (TW)

(73) Assignee: Winbond Electronics Corp., Taichung City (TW)

(21) Appl. No.: 19/067,994

(22) Filed: Mar. 3, 2025

(30) Foreign Application Priority Data
Mar. 21, 2024 (TW) 113110428

(51) Int. Cl. H10D 89/60

(52) U.S. Cl. CPC H10D 89/713; H10D 89/611

(57) ABSTRACT

An input/output driver including an electrostatic discharge protection circuit is provided. The electrostatic discharge protection circuit has a silicon controlled rectifier including first to fourth heavily doped regions that are respectively disposed in surface regions of first to fourth well regions of a substrate. The first to fourth well regions are arranged sequentially along a first direction and adjacent to each other. The first and third well regions and the first and third heavily doped regions are of a first conductivity type. The second and fourth well regions and the second and fourth heavily doped regions are of a second conductivity type. The second heavily doped region further extends into the first and third well regions, and is immediately adjacent to the first and third heavily doped regions. The fourth heavily doped region further extends into the third well region and is immediately adjacent to the third heavily doped region.

### CROSS-REFERENCE TO RELATED APPLICATION

This application claims the priority benefit of Taiwan application serial no. 113110428, filed on Mar. 21, 2024. The entirety of the above-mentioned patent application is hereby incorporated by reference herein and made a part of this specification.

### BACKGROUND

### Technical Field

The disclosure relates to an input/output driver, and in particular to an input/output driver capable of forming an embedded silicon controlled rectifier (SCR) structure.

### Description of Related Art

Input/output (I/O) drivers are used to receive input voltages, which change between high logic voltages and low logic voltages that relate to specific core voltage regions, from I/O terminals of a memory device. Conventionally, an I/O driver require an additional layout area for each I/O terminal to configure on-chip electrostatic discharge (ESD) diodes and resistors used to protect the drive circuit. It is challenging to further improve the electrostatic protection capacity when a considerable layout area is already consumed.

### SUMMARY

The disclosure provides an input/output driver capable of providing an improved electrostatic protection by efficiently utilizing a layout area.

An input/output driver of the disclosure includes an electrostatic discharge protection circuit. The electrostatic discharge protection circuit has a silicon controlled rectifier connected between an input/output terminal and a power supply terminal. The electrostatic discharge protection circuit also includes a first heavily doped region, a second heavily doped region, a third heavily doped region, and a fourth heavily doped region disposed in surface regions of a first well region, a second well region, a third well region, and a fourth well region of a substrate respectively.

The first to fourth well regions are arranged sequentially along a first direction and adjacent to each other. The first and third well regions and the first and third heavily doped regions are of a first conductivity type. The second and fourth well regions and the second and fourth heavily doped regions are of a second conductivity type. The second heavily doped region further extends into the first and third well regions, and is immediately adjacent to the first and third heavily doped regions. The fourth heavily doped region further extends into the third well region and is immediately adjacent to the third heavily doped region.

Based on the above, the disclosure forms a silicon controlled rectifier in the input/output driver by efficiently utilizing a layout area. In this way, the layout area may be saved while better electrostatic protection is provided by increasing the quantity of discharge paths, thereby meeting the requirements for miniaturization and cost reduction.

In order to make the above-mentioned and other features and advantages of the disclosure more comprehensible, several exemplary embodiments are described in detail hereinafter with reference to the accompanying drawings.

### BRIEF DESCRIPTION OF THE DRAWINGS

FIG. 1 is a circuit schematic diagram of an input/output driver according to an embodiment of the disclosure.

FIG. 2A is a partial three-dimensional schematic diagram of an electrostatic discharge protection circuit in FIG. 1.

FIGS. 2B and 2C are cross-sectional schematic diagrams along a cutline X-X′ in FIG. 2A.

FIG. 2D is a cross-sectional schematic diagram along a cutline Y-Y′ in FIG. 2A.

FIG. 3 illustrates a way of configuring an input/output driver in a memory chip according to an embodiment of the disclosure.

### DESCRIPTION OF THE EMBODIMENTS

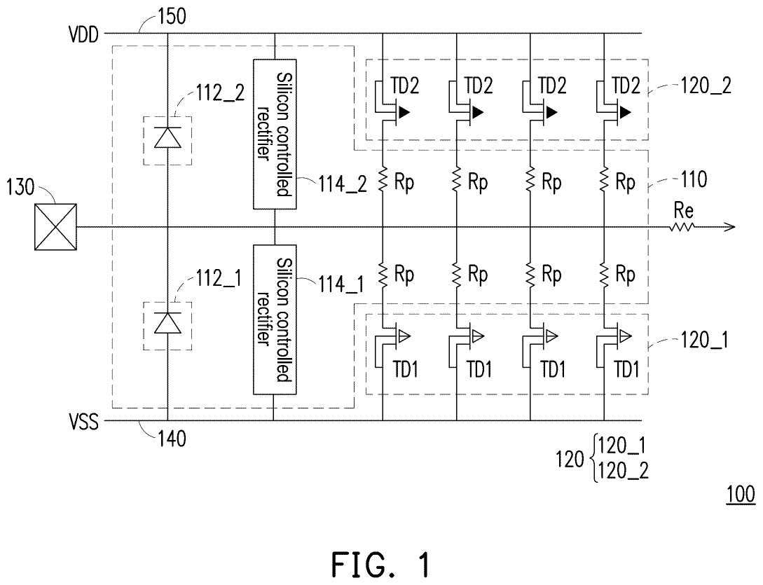

Referring to FIG. 1, an input/output (I/O) driver 100 is, for example, an off-chip driver used for a memory device. The I/O driver 100 includes an electrostatic discharge (ESD) protection circuit 110 and a drive circuit 120. The ESD protection circuit 110 includes a diode circuit 112_1, a diode circuit 112_2, a silicon controlled rectifier 114_1, a silicon controlled rectifier 114_2, and multiple protective resistors Rp. The diode circuit 112_1 includes multiple diodes connected between an I/O terminal 130 and a power supply terminal 140. The diode circuit 112_2 includes multiple diodes connected between the I/O terminal 130 and a power supply terminal 150. The power supply terminal 140 is used to receive a ground voltage VSS and the power supply terminal 150 is used to receive a power supply voltage VDD. In addition, the I/O terminal 130 may be coupled to other memory peripheral circuits or devices through a resistor Re. The resistor Re may, for example, prevent a current from flowing to a memory peripheral circuit or device in conditions of insufficient discharge paths or an overlarge current. A resistance value of the resistor Re may be adjusted according to the type and specification of the memory device for which the I/O driver 100 is suitable.

The silicon controlled rectifier 114_1 is connected in parallel with the diode circuit 112_1 between the I/O terminal 130 and the power supply terminal 140. The silicon controlled rectifier 114_2 is connected in parallel with the diode circuit 112_2 between the I/O terminal 130 and the power supply terminal 150. It is noted that the silicon controlled rectifier 114_1 and the silicon controlled rectifier 114_2 in this embodiment are of an embedded type and formed through a parasitic effect. That is, the silicon controlled rectifier 114_1 and the silicon controlled rectifier 114_2 are formed between electronic elements or circuit modules of the I/O driver 100 due to the silicon controlled rectifier 114_1 and the silicon controlled rectifier 114_2 getting close to each other. Thus, rectification operations may be performed without applying a gate voltage. References may be made to the embodiments described later for detailed examples of the formation.

In FIG. 1, the drive circuit 120 includes a first drive circuit 120_1 and a second drive circuit 120_2. The first drive circuit 120_1 includes multiple drive transistors TD1 connected between the corresponding protective resistors Rp and the power supply terminal 140 respectively. The second drive circuit 120_2 includes multiple drive transistors TD2 connected between the corresponding protective resistors Rp and the power supply terminal 150 respectively. The protective resistor Rp may be used to prevent a current from flowing to a corresponding drive transistor, thereby protecting the drive circuit 120.

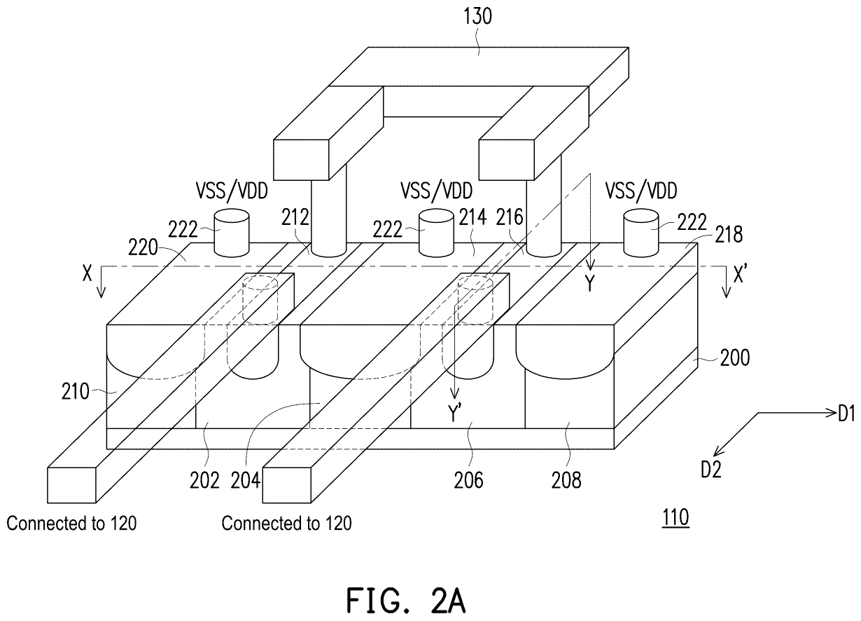

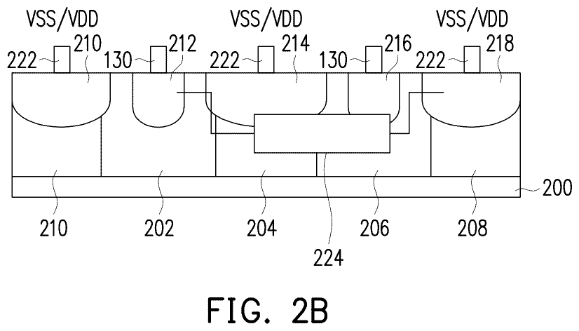

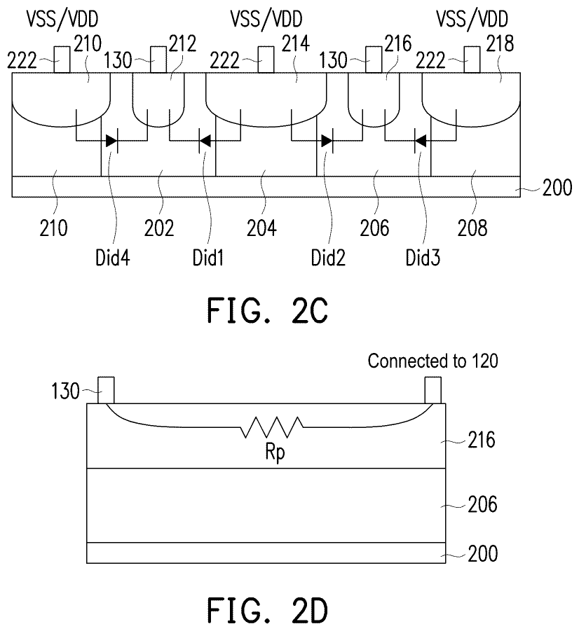

FIG. 2A is a partial three-dimensional schematic diagram of the ESD protection circuit 110 in FIG. 1. FIGS. 2B and 2C are cross-sectional schematic diagrams along a cutline X-X′ in FIG. 2A. FIG. 2D is a cross-sectional schematic diagram along a cutline Y-Y′ in FIG. 2A.

Referring to FIGS. 2A to 2D at the same time, the ESD protection circuit 110 includes a first well region 202, a second well region 204, a third well region 206, a fourth well region 208, and a fifth well region 210 disposed in a substrate 200 respectively. The ESD protection circuit 110 also includes a first heavily doped region 212, a second heavily doped region 214, a third heavily doped region 216, a fourth heavily doped region 218, and a fifth heavily doped region 220 disposed in surface regions of the first well region 202, the second well region 204, the third well region 206, the fourth well region 208, and the fifth well region 210 respectively. The substrate 200 includes a semiconductor substrate or a semiconductor on insulator (SOI) substrate.

The first well region 202 to the fourth well region 208 are arranged sequentially along a first direction D1 and adjacent to each other. The first well region 202 is adjacent to the second well region 204 and the fifth well region 210 on two opposite sides. In addition, the first heavily doped region 212 and the third heavily doped region 216 are coupled to the I/O terminal 130. The second heavily doped region 214, the fourth heavily doped region 218, and the fifth heavily doped region 220 are coupled to a power supply terminal 222.

The first well region 202, the third well region 206, the first heavily doped region 212, and the third heavily doped region 216 may be doped to be of a first conductivity type. The second well region 204, the fourth well region 208, the fifth well region 210, the second heavily doped region 214, the fourth heavily doped region 218, and the fifth heavily doped region 220 may be doped to be of a second conductivity type. In some embodiments, the first conductivity type may be N-type, and the second conductivity type may be P-type. In this case, the power supply terminal 222 in FIGS. 2A to 2C may correspond to the power supply terminal 140 in FIG. 1 and be used to receive the ground voltage VSS. In some embodiments, the first conductivity type may also be P-type, and the second conductivity type may be N-type. In this case, the power supply terminal 222 in FIGS. 2A to 2C may correspond to the power supply terminal 150 in FIG. 1 and be used to receive the power supply voltage VDD. For example, an N-type dopant includes phosphorus or arsenic, and a P-type dopant may include boron. A dopant concentration in a heavily doped region is greater than a dopant concentration in a well region of the same conductivity type.

In this embodiment, the second heavily doped region 214 further extends into the first well region 202 and the third well region 206 along the first direction D1, and is immediately adjacent to the first heavily doped region 212 and the third heavily doped region 216. The fourth heavily doped region 218 further extends into the third well region 206 along the first direction D1, and is immediately adjacent to the third heavily doped region 216. The fifth heavily doped region 220 further extends into the first well region 202 along the first direction D1 and is immediately adjacent to the first heavily doped region 212. As a result, an avalanche breakdown effect of a P-N contact surface is enhanced and reverse bias currents of the P-N contact surface are increased, thereby reducing a threshold voltage between a well region and a heavily doped region. In this way, as shown in FIG. 2B, the first heavily doped region 212 to the fourth heavily doped region 218 of the ESD protection circuit 110 may form an embedded silicon controlled rectifier 224, connected between the I/O terminal 130 and the power supply terminal 222, along the first direction D1 due to the parasitic effect, thereby increasing the quantity of discharge paths and providing better electrostatic protection. It is noted that in case of the first conductivity type being N-type and the second conductivity type being the P-type, the silicon controlled rectifier 224 may correspond to the silicon controlled rectifier 114_1 in FIG. 1. In case of the first conductivity type being P-type and the second conductivity type being the N-type, the silicon controlled rectifier 224 may correspond to the silicon controlled rectifier 114_2 in FIG. 1.

The I/O driver 100 further includes a first diode Did1, a second diode Did2, a third diode Did3, and a fourth diode Did4 connected to the I/O terminal 130 and the power supply terminal 222. As shown in FIG. 2C, the first diode Did1 is defined in an interface between the first well region 202 and the second well region 204 along the first direction D1. The second diode Did2 is defined in an interface between the second well region 204 and the third well region 206 along the first direction D1. The third diode Did3 is defined in an interface between the third well region 206 and the fourth well region 208 along the first direction D1. The fourth diode Did4 is defined in an interface between the first well region 202 and the fifth well region 210 along the first direction D1. It is noted that in FIG. 2C, the anode-to-cathode directions of the first diode Did1 to the fourth diode Did4 are illustrated as examples in case of the first conductivity type being N-type and the second conductivity type being P-type, and that the first diode Did1 to the fourth diode Did4 may serve as the diodes included in the diode circuit 112_1 in FIG. 1. In case of the first conductivity type being P-type and the second conductivity type being N-type, the anode-to-cathode directions of the first diode Did1 to the fourth diode Did4 are reversed from the anode-to-cathode directions shown in FIG. 2C, and the first diode Did1 to the fourth diode Did4 may serve as the diodes included in the diode circuit 112_2 in FIG. 1.

The first heavily doped region 212 and the third heavily doped region 216 are further connected to the drive circuit 120 respectively. Specifically, the first heavily doped region 212 to the fifth heavily doped region 220 extend along a second direction D2 intersecting with the first direction D1. Further, the first heavily doped region 212 and the third heavily doped region 216 are connected to the I/O terminal 130 and the drive circuit 120 respectively through two opposite ends. Taking the third heavily doped region 216 as an example, as shown in FIG. 2D, the protective resistors Rp may be formed between an I/O terminal 130 and a drive circuit 120 respectively in the third heavily doped region 216 along the second direction D2.

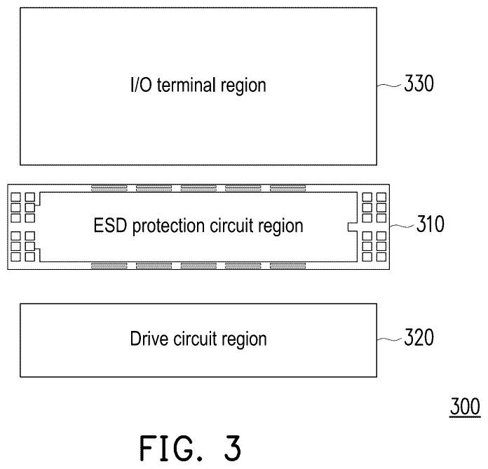

Referring to FIG. 3, a circuit region 300 of an I/O driver in a chip includes an ESD protection circuit region 310, a drive circuit region 320, and an I/O terminal region 330. Through methods introduced in the above embodiments, including forming silicon controlled rectifiers and diodes in the ESD protection circuit along the first direction D1 and, in a two-dimensional concept, forming protective resistors along the second direction D2, all of the silicon controlled rectifiers, diodes, and protective resistors may be integrated into the ESD protection circuit region 310. As a result, about 50% of the layout area may be saved, thereby meeting the requirements for miniaturization and cost reduction.

In summary, the disclosure forms a silicon controlled rectifier in the input/output driver by efficiently utilizing a layout area. In addition, a protective resistor used to protect a drive circuit may be integrated in the same area where the silicon controlled rectifier is located. In this way, the layout area may be saved while better electrostatic protection is provided by increasing the quantity of discharge paths, thereby meeting the requirements for miniaturization and cost reduction.

What is claimed is:

1. An input/output driver, comprising:
an electrostatic discharge protection circuit, having a silicon controlled rectifier connected between an input/output terminal and a power supply terminal, and comprising:
a first heavily doped region, a second heavily doped region, a third heavily doped region, and a fourth heavily doped region, disposed in surface regions of a first well region, a second well region, a third well region, and a fourth well region of a substrate respectively, wherein the first well region to the fourth well region are arranged sequentially along a first direction and adjacent to each other, wherein the first well region, the third well region, the first heavily doped region, and the third heavily doped region are of a first conductivity type, and the second well region, the fourth well region, the second heavily doped region, and the fourth heavily doped region are of a second conductivity type, the second heavily doped region further extending into the first well region and the third well region and being immediately adjacent to the first heavily doped region and the third heavily doped region, and the fourth heavily doped region further extending into the third well region and being immediately adjacent to the third heavily doped region.

2. The input/output driver of claim 1, wherein the first heavily doped region and the third heavily doped region are coupled to the input/output terminal.

3. The input/output driver of claim 1, wherein the second heavily doped region and the fourth heavily doped region are coupled to the power supply terminal.

4. The input/output driver of claim 3, wherein the power supply terminal receives a ground voltage.

5. The input/output driver of claim 3, wherein the power supply terminal receives a power supply voltage.

6. The input/output driver of claim 1, further comprising a drive circuit, the drive circuit comprising a plurality of drive transistors, wherein the first heavily doped region and the third heavily doped region are further connected to the drive circuit respectively.

7. The input/output driver of claim 6, wherein the first heavily doped region to the fourth heavily doped region extend in a second direction intersecting with the first direction, and the first heavily doped region and the third heavily doped region are connected to the input/output terminal and the drive circuit respectively through two opposite ends.

8. The input/output driver of claim 7, wherein a protective resistor connected between the input/output terminal and the drive circuit is formed in the first heavily doped region and the third heavily doped region respectively.

9. The input/output driver of claim 1, further comprising a plurality of diodes connected between the input/output terminal and the power supply terminal.

10. The input/output driver of claim 9, wherein the plurality of diodes comprise:
a first diode, defined in an interface between the first well region and the second well region;
a second diode, defined in an interface between the second well region and the third well region; and
a third diode, defined in an interface between the third well region and the fourth well region.

11. The input/output driver of claim 9, wherein the electrostatic discharge protection circuit further comprises a fifth well region, disposed in the substrate and being of the second conductivity type, and a fifth heavily doped region, disposed in a surface region of the fifth well region.

12. The input/output driver of claim 11, wherein the first well region being adjacent to the second well region and the fifth well region on two opposite sides, and the fifth heavily doped region further extending into the first well region and being immediately adjacent to the first heavily doped region.

13. The input/output driver of claim 11, wherein the plurality of diodes comprise a fourth diode defined in an interface between the first well region and the fifth well region.
